(19) United States
(12) Patent Application Publication
(10) Pub. No.: US 2024/0276781 A1
(43) Pub. Date: Aug. 15, 2024

(54) DISPLAY DEVICE AND METHOD FOR MANUFACTURING THE SAME

(71) Applicant: Samsung Display Co., Ltd., Yongin-si (KR)

(72) Inventor: CHUNGI YOU, Yongin-si (KR)

(21) Appl. No.: 18/390,511

(22) Filed: Dec. 20, 2023

(30) Foreign Application Priority Data
Feb. 14, 2023 (KR) 10-2023-0019585

(51) Int. Cl. H10K 59/122; H10K 59/12

(52) U.S. Cl. CPC H10K 59/122; H10K 59/1201

(57) ABSTRACT

A display device includes: a base substrate including a first pixel area and a second pixel area; a first pixel electrode in the first pixel area on the base substrate; a second pixel electrode in the second pixel area on the base substrate; a first partition wall between the first pixel electrode and the second pixel electrode; and a first pixel defining layer on a part of each of the first and second pixel electrodes, exposing at least a part of an upper surface of each of the first and second pixel electrodes, and having an upper surface at a same level as an upper surface of the first partition wall with respect to a surface of the base substrate.

### CROSS-REFERENCE TO RELATED APPLICATION

The present application claims priority to and the benefit of Korean Patent Application No. 10-2023-0019585, filed on Feb. 14, 2023 in the Korean Intellectual Property Office (KIPO), the entire content of which is incorporated herein by reference.

### BACKGROUND

### 1. Field

Aspects of some embodiments include a display device and a method for manufacturing the same.

### 2. Description of the Related Art

With the development of information technology, the importance of a display device, which provides a connection medium between a user and information, has been highlighted. For example, the use of a display device such as a liquid crystal display device, an organic light emitting display device, a plasma display device, and the like is increasing.

Recently, a head-mounted display (“HMD”) including such a display device has been developed. The head-mounted display may be a virtual reality (“VR”) or augmented reality (“AR”) glasses-type monitor device that is capable of being worn in the form of glasses or a helmet and focuses on a distance close to the user's eyes. The head-mounted display may provide an image displayed on the display device to the user's eyes through a lens.

Meanwhile, a high-resolution micro OLED may be utilized in the head-mounted display, and the high-resolution micro OLED may be an organic light emitting diode on silicon (“OLEDos”) formed using a silicon wafer-based semiconductor process.

The above information disclosed in this Background section is only for enhancement of understanding of the background and therefore the information discussed in this Background section does not necessarily constitute prior art.

### SUMMARY

Aspects of some embodiments include a display device and a method for manufacturing the same. For example, aspects of some embodiments relate to a display device that provides visual information and a method for manufacturing the same.

Aspects of some embodiments include a display device with relatively reduced power consumption.

Aspects of some embodiments include a method for manufacturing the display device.

A display device according to some embodiments of the present disclosure includes a base substrate including a first pixel area and a second pixel area, a first pixel electrode in the first pixel area on the base substrate, a second pixel electrode in the second pixel area on the base substrate, a first partition wall between the first pixel electrode and the second pixel electrode, and a first pixel defining layer on a part of each of the first and second pixel electrodes, exposing at least a part of an upper surface of each of the first and second pixel electrodes, and having an upper surface positioned at a same level as an upper surface of the first partition wall with respect to a surface of the base substrate.

According to some embodiments, at least one end of each of the first and second pixel electrodes may be vertically bent. According to some embodiments, an upper surface of the one end of each of the first and second pixel electrodes may be positioned at a same layer as the upper surface of each of the first partition wall and the first pixel defining layer with respect to the surface of the base substrate.

According to some embodiments, the display device may further include a first pixel protection layer between the base substrate and the first pixel electrode and including a conductive material and a second pixel protection layer between the base substrate and the second pixel electrode and including a same conductive material as the first pixel protection layer.

According to some embodiments, each of the first and second pixel protection layers may include titanium nitride (TiN).

According to some embodiments, the display device may further include a second pixel defining layer on a part of the first pixel defining layer and the first partition wall and exposing at least a part of the upper surface of each of the first and second pixel electrodes.

According to some embodiments, the first pixel defining layer and the second pixel defining layer may include different inorganic materials.

According to some embodiments, the first pixel defining layer may include silicon oxide (SiOₓ) and the second pixel defining layer may include silicon nitride (SiNₓ).

According to some embodiments, a side surface of the first pixel defining layer may protrude further in a direction away from a center of the second pixel defining layer than a side surface of the second pixel defining layer.

According to some embodiments, the display device may further include a second partition wall on the second pixel defining layer, overlapping the first partition wall, and includes an inorganic material.

According to some embodiments, the second partition wall may include a first sub-layer and a second sub-layer on the first sub-layer and including an inorganic material different from an inorganic material of the first sub-layer.

According to some embodiments, a side surface of the second sub-layer may protrude further in a direction away from a center of the first sub-layer than a side surface of the first sub-layer.

According to some embodiments, the base substrate may further include a third pixel area. According to some embodiments, the display device may further include a third pixel electrode in the third pixel area on the base substrate, a first light emitting layer on the first pixel electrode and including a light emitting material that emits red light, a second light emitting layer on the second pixel electrode and including a light emitting material that emits green light, and a third light emitting layer on the third pixel electrode and including a light emitting material that emits blue light.

According to some embodiments, the first partition wall may include silicon nitride.

According to some embodiments, the base substrate may include a silicon wafer.

A method for manufacturing the display device according to some embodiments of the present disclosure includes: forming a preliminary first partition wall on a base substrate including a first pixel area and a second pixel area, forming a preliminary electrode layer covering the preliminary first partition wall on the base substrate and the preliminary first partition wall, forming a preliminary first pixel defining layer on the preliminary electrode layer, forming a first pixel electrode in the first pixel area, a second pixel electrode in the second pixel area, and a first partition wall between the first and second electrodes by performing a planarization process on an entire surface of the base substrate, and forming a first pixel defining layer exposing at least a part of an upper surface of each of the first and second pixel electrodes by removing a part of the preliminary first pixel defining layer.

According to some embodiments, in the forming the first pixel electrode, the second pixel electrode, and the first partition wall, a part of each of the preliminary first partition wall, the preliminary electrode layer, and the preliminary first pixel defining layer may be removed. According to some embodiments, at least one end of each of the first and second pixel electrodes may be vertically bent and an upper surface of the first partition wall may be positioned at a same level as an upper surface of the preliminary first pixel defining layer with respect to a surface of the base substrate after the forming the first pixel electrode, the second pixel electrode, and the first partition wall.

According to some embodiments, in the forming the preliminary electrode layer, the preliminary electrode layer may be formed to a uniform thickness along a profile of the preliminary first partition wall. According to some embodiments, in the forming the preliminary first pixel defining layer, the preliminary first pixel defining layer may be formed to a uniform thickness along a profile of the preliminary electrode layer.

According to some embodiments, the forming the first pixel electrode, the second pixel electrode, and the first partition wall may be performed through a chemical mechanical planarization (“CMP”) process.

According to some embodiments, before the forming the first partition wall, the method may further include forming a first pixel protection layer including a conductive material in the first pixel area on the base substrate and forming a second pixel protection layer including a same conductive material as the first pixel protection layer in the second pixel area on the base substrate. According to some embodiments, the first pixel protection layer may be formed between the base substrate and the first pixel electrode and the second pixel protection layer may be formed between the base substrate and the second pixel electrode.

According to some embodiments, after the first pixel electrode, the second pixel electrode, and the first partition wall and before the first pixel defining layer, the method may further include forming a preliminary second pixel defining layer on the first partition layer, the first pixel electrode, the second pixel electrode, and the preliminary first pixel defining layer and forming a second pixel defining layer exposing at least a part of an upper surface of the preliminary first pixel defining layer in each of the first and second pixel areas. According to some embodiments, after the forming the first pixel defining layer, the second pixel defining layer may expose at least a part of an upper surface of each of the first and second electrodes.

A display device according to some embodiments of the present disclosure includes: first, second, and third pixel electrodes respectively on first, second, and third pixel areas on a base substrate, a first partition wall between two pixel electrodes among the first, second, and third pixel electrodes, a first pixel defining layer on a part of each of the first, second, and third pixel electrodes and exposing at least a part of an upper surface of each of the first, second, and third pixel electrodes, and a second pixel defining layer on the first partition wall. Here, with respect to the surface of the base substrate, an upper surface of the first partition wall may be positioned at the same level as an upper surface of the first pixel defining layer. Accordingly, a light emitting layer including a light emitting material that emits one color can be independently in each of the first, second, and third pixel areas. In addition, power consumption of the display device can be relatively reduced.

In addition, in the method for manufacturing the display device according to some embodiments of the present disclosure, a preliminary electrode layer may be formed on the base substrate, and a part of the preliminary electrode layer may be removed through a planarization process to form a pixel electrode. Accordingly, the pixel electrode can be relatively easily formed.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to some embodiments of the present disclosure.

FIG. 2 is a cross-sectional view taken along the line I-I′ of FIG. 1 according to some embodiments of the present disclosure.

FIG. 3 is a cross-sectional view taken along the line II-II′ of FIG. 1 according to some embodiments of the present disclosure.

FIGS. 4 to 25 are cross-sectional views for explaining a method for manufacturing the display device of FIGS. 2 and 3 according to some embodiments of the present disclosure.

### DETAILED DESCRIPTION

Hereinafter, aspects of a display device according to some embodiments of the present disclosure will be explained in more detail with reference to the accompanying drawings. The same reference numerals are used for the same components in the drawings, and redundant descriptions of the same components will be omitted.

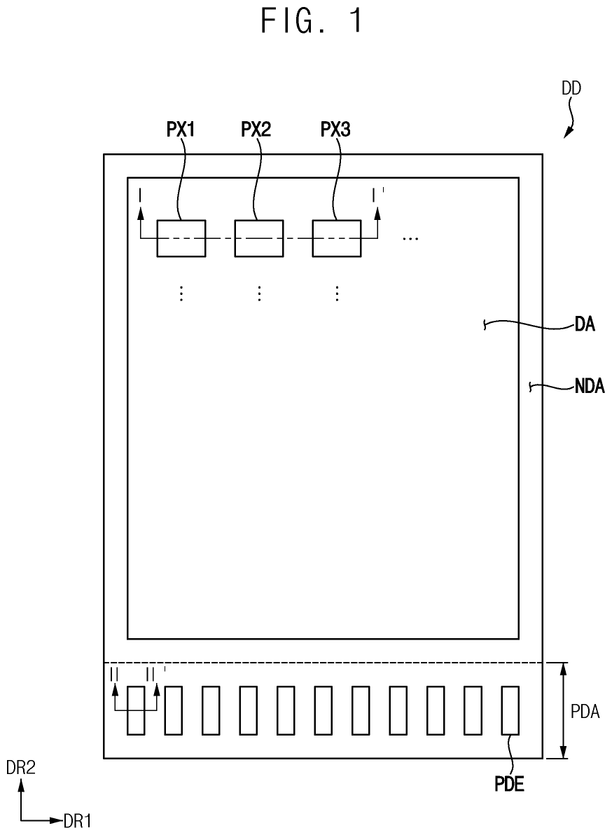

FIG. 1 is a plan view illustrating a display device according to some embodiments of the present disclosure.

Referring to FIG. 1, a display device DD according to some embodiments may include a display area DA and a non-display area NDA. The display area DA may be an area capable of displaying images by generating light or adjusting transmittance of light provided from an external light source. The non-display area NDA may be an area that does not display images. The non-display area NDA may be positioned around (e.g., in a periphery or outside a footprint of) the display area DA. For example, the non-display area NDA may entirely surround the display area DA.

The display area DA may include a plurality of pixel areas. The pixel areas may be arranged in a matrix configuration or arrangement of rows and columns extending along a first direction DR1 and a second direction DR2 crossing the first direction DR1. For example, the pixel areas may include a first pixel area PX1, a second pixel area PX2, and a third pixel area PX3.

Each of the first pixel area PX1, the second pixel area PX2, and the third pixel area PX3 may refer to an area where light emitted from the light emitting element is emitted to the outside of the display device DD. For example, the first pixel area PX1 may emit a first color of light, the second pixel area PX2 may emit a second color of light, and the third pixel area PX3 may emit a third color of light. According to some embodiments, the first light may be red light, the second light may be green light, and the third light may be blue light. However, embodiments according to the present disclosure are not limited thereto. For example, the first, second, and third pixel areas PX1, PX2, and PX3 may be combined to emit yellow, cyan, and magenta lights.

The first, second, and third pixel areas PX1, PX2, and PX3 may emit light of four or more colors. For example, the first, second, and third pixel areas PX1, PX2, and PX3 may be combined to further emit at least one of yellow, cyan, or magenta lights in addition to red, green, and/or blue lights. In addition, the first, second, and third pixel areas PX1, PX2, and PX3 may be combined to further emit white light.

Each of the first pixel area PX1, the second pixel area PX2, and the third pixel area PX3 may have a triangular planar shape, a quadrangular planar shape, a circular planar shape, an elliptical planar shape, or the like. According to some embodiments, each of the first pixel area PX1, the second pixel area PX2, and the third pixel area PX3 may have a rectangular planar shape. However, the embodiments of the present disclosure are not limited thereto, and each of the first pixel area PX1, the second pixel area PX2, and the third pixel area PX3 may have a different planar shape.

The non-display area NDA may include a pad area PDA. The pad area PDA may be spaced apart from one side of the display area DA. For example, the pad area PDA may have a shape extending in the first direction DR1.

A plurality of lines may be located in the non-display area NDA, and a plurality of pad electrodes PDE may be located in the pad area PDA. The lines may electrically connect the pad electrodes PDE and the pixel areas. For example, the lines may include data signal lines, scan signal lines, light emitting control signal lines, and power supply voltage lines.

The pad electrodes PDE may be arranged to be spaced apart from each other in the first direction DR1. For example, each of the pad electrodes PDE may include a metal, an alloy, a metal nitride, a conductive metal oxide, a transparent conductive material, and the like. These may be used alone or in combination with each other.

In this specification, a plane may be defined as the first direction DR1 and the second direction DR2 crossing the first direction DR1. For example, the first direction DR1 may be perpendicular to the second direction DR2.

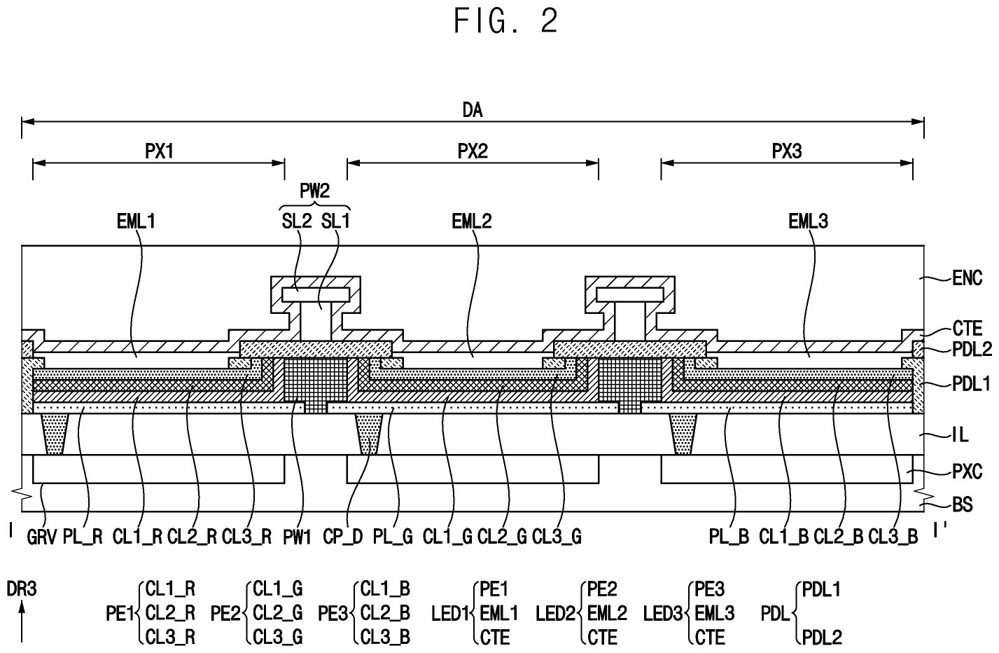

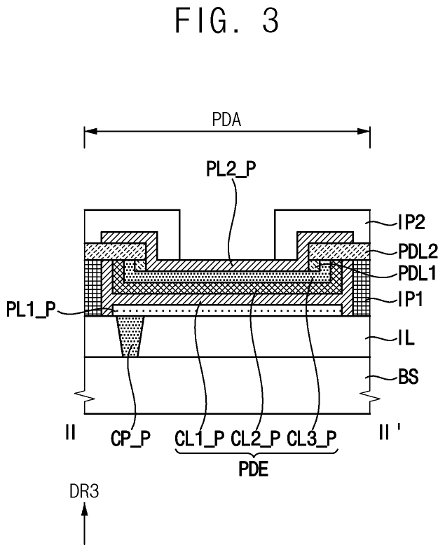

FIG. 2 is a cross-sectional view taken along the line I-I′ of FIG. 1. FIG. 3 is a cross-sectional view taken along the line II-II′ of FIG. 1.

Referring to FIGS. 2 and 3, the display device DD according to some embodiments of the present disclosure may include a base substrate BS, a pixel circuit portion PXC, an insulating layer IL, a pixel connection pattern CP_D, a pad connection. pattern CP_P, first, second, and third pixel protection layers PL_R, PL_G, and PL_B, a first pad protection layer PL1_P, a first partition wall PW1, a first insulating pattern IP1, a pixel definition layer PDL, first, second, and third light emitting elements LED1, LED2, and LED3, the pad electrode PDE, a second pad protection layer PL2_P, a second partition wall PW2, a second insulating pattern IP2, and an encapsulation layer ENC.

Here, the first light emitting element LED1 may include a first pixel electrode PE1, a first light emitting layer EML1, and a common electrode CTE, the second light emitting element LED2 may include a second pixel electrode PE2, a second light emitting layer EML2, and a common electrode CTE, and the third light emitting element LED3 may include a third pixel electrode PE3, a third light emitting layer EML3, and a common electrode CTE.

As described above, the display device DD may include the display area DA including the first, second, and third pixel areas PX1, PX2, and PX3 and the non-display area NDA. As the display device DD includes the display area DA including the first, second, and third pixel areas PX1, PX2, and PX3 and the non-display area NDA, the base substrate BS may also include the display area DA including the first, second, and third pixel areas PX1, PX2, and PX3 and the non-display area NDA.

According to some embodiments, the base substrate BS may include a silicon wafer. The base substrate BS may be a support member for supporting other components of the display device DD. The base substrate BS may define a plurality of grooves GRV in the display area DA. The grooves GRV may overlap each of the first, second, and third pixel areas PX1, PX2, and PX3.

The pixel circuit portion PXC may be located in each of the grooves GRV. That is, the pixel circuit portion PXC may be located in each of the first, second, and third pixel areas PX1, PX2, and PX3. The pixel circuit portion PXC may include various driving elements and lines for driving the light emitting elements. For example, the pixel circuit portion PXC may include various components such as transistors, storage capacitors, scan signal lines, data signal lines, and the like.

The insulating layer IL may be located on the pixel circuit unit PXC. The insulating layer IL may be located in the display area DA and the pad area PDA. The insulating layer IL may prevent or reduce contact between the first, second, and third pixel electrodes PE1, PE2, and PE3 and the pixel circuit portion PXC. The insulating layer IL may include an organic material and/or an inorganic material. For example, the insulating layer IL may include an inorganic material such as silicon oxide (SiOₓ), silicon nitride (SiNₓ), silicon oxynitride (SiOₓN_{y}), and the like. These may be used alone or in combination with each other.

In the display area DA, a first contact hole penetrates a part of the insulating layer IL and overlapping the first pixel area PX1, a second contact hole penetrates a part of the insulating layer IL and overlapping the second pixel area PX2, and a third contact hole penetrates a part of the insulating layer IL and overlapping the third pixel area PX3 may be defined. In addition, in the pad area PDA, a fourth contact hole penetrating a part of the insulating layer IL may be defined.

The pixel connection pattern CP_D may be filled in each of the first, second, and third contact holes, and the pad connection pattern CP_P may be filled in the fourth contact hole.

The pixel connection pattern CP_D may be electrically connected to the pixel circuit portion PXC in the display area DA, and the pad connection pattern CP_P may be electrically connected to the pixel areas of the display area DA. For example, each of the pixel connection pattern CP_D and the pad connection pattern CP_P may include a conductive material. According to some embodiments, each of the pixel connection pattern CP_D and the pad connection pattern CP_P may include tungsten (W).

The first, second, and third pixel protection layers PL_R, PL_G, and PL_B may be located in the display area DA on the insulating layer IL. The first, second, and third pixel protection layers PL_R, PL_G, and PL_B may protect an area where the first, second, and third pixel electrodes PE1, PE2, and PE3 are located when the first partition wall PW1 is formed. The first pixel protection layer PL_R may overlap the first pixel area PX1, the second pixel protection layer PL_G may overlap the second pixel area PX2, and the third pixel protection layer PL_B may overlap the third pixel area PX3. Each of the first, second, and third pixel protection layers PL_R, PL_G, and PL_B may be connected to the pixel connection pattern CP_D. Each of the first, second, and third pixel protection layers PL_R, PL_G, and PL_B may include a conductive material. According to some embodiments, each of first, second, and third pixel protection layers PL_R, PL_G, and PL_B may include titanium nitride (TiN).

The first pad protection layer PL1_P may be located in the pad area PDA on the insulating layer IL. The first pad protection layer PL1_P may protect an area where the pad electrode PDE is located when the first insulating pattern IP1 is formed. The first pad protection layer PL1_P may be connected to the pad connection pattern CP_P. The first pad protection layer PL1_P may include the same material as the first, second, and third pixel protection layers PL_R, PL_G, and PL_B and may be formed through the same process as the first, second, and third pixel protection layers PL_R, PL_G, and PL_B.

The first partition wall PW1 may be located in the display area DA on the insulating layer IL. The first partition wall PW1 may cover side parts of each of the first, second, and third pixel protection layers PL_R, PL_G, and PL_B. The first partition wall PW1 may have a substantially flat upper surface.

The first partition wall PW1 may include an inorganic material. For example, the first partition wall PW1 may include an inorganic material such as silicon oxide (SiOₓ), silicon nitride (SiNₓ), silicon oxynitride (SiOₓN_{y}), and the like. According to some embodiments, the first partition wall PW1 may include silicon nitride.

The first insulating pattern IP1 may be located in the pad area PDA on the insulating layer IL. The first insulating pattern IP1 may be spaced apart from the first pad protection layer PL1_P. The first insulating pattern IP1 may include the same material as the first partition wall PW1 and may be formed through the same process as the first partition wall PW1.

The first pixel electrode PE1 may be located on the first pixel protection layer PL_R, the second pixel electrode PE2 may be located on the second pixel protection layer PL_G, and the third pixel electrode PE3 may be located on the third pixel passivation layer PL_B. The first pixel electrode PE1 may overlap the first pixel area PX1, the second pixel electrode PE2 may overlap the second pixel area PX2, and the third pixel electrode PE3 may overlap the third pixel area PX3. For example, the first pixel electrode PE1 may be electrically connected to the first pixel passivation layer PL_R, the second pixel electrode PE2 may be electrically connected to the second pixel passivation layer PL_G, and the third pixel electrode PE3 may be electrically connected to the third pixel passivation layer PL_B.

The first, second, and third pixel electrodes PE1, PE2, and PE3 may be arranged with the first partition wall PW1 interposed therebetween. For example, the first partition wall PW1 may be located between the first and second pixel electrodes PE1 and PE2 and between the second and third pixel electrodes PE2 and PE3.

According to some embodiments, at least one end of each of the first, second, and third pixel electrodes PE1, PE2, and PE3 may be vertically bent. That is, at least one end of each of the first, second, and third pixel electrodes PE1, PE2, and PE3 may be bent in a thickness direction (e.g., in the third direction DR3). For example, one end of each of the first and third pixel electrodes PE1 and PE3 may be vertically bent, and one end and the other end of the second pixel electrode PE2 may be vertically bent.

According to some embodiments, an upper surface of at least one end of each of the first, second, and third pixel electrodes PE1, PE2, and PE3 may be positioned at the same level as an upper surface of the first partition wall PW1 with respect to a surface of the base substrate BS. However, the embodiments of the present disclosure are not limited thereto, and the upper surface of at least one end of each of the first, second, and third pixel electrodes PE1, PE2, and PE3 may be positioned at a different level from the upper surface of the first partition PW1 with respect to a surface of the base substrate BS.

At least one end of each of the first, second, and third pixel electrodes PE1, PE2, and PE3 may have a substantially flat upper surface.

Each of the first, second, and third pixel electrodes PE1, PE2, and PE3 may include a metal, an alloy, a metal nitride, a conductive metal oxide, a transparent conductive material, and the like. According to some embodiments, each of the first, second, and third pixel electrodes PE1, PE2, and PE3 may have a multilayer structure including ITO/Ag/ITO. For example, each of the first, second, and third pixel electrodes PE1, PE2, and PE3 may include a first conductive layer CL1_R, CL1_G, or CL1_B including ITO, a second conductive layer CL2_R, CL2_G, or CL2_B including Ag, and a third conductive layer CL3_R, CL3_G, or CL3_B including ITO that are sequentially stacked.

The pad electrode PDE may be located in the pad area PDA on the first pad protection layer PL1_P. The pad electrode PDE may be electrically connected to the first pad protection layer PL1_P. According to some embodiments, at least one end of one side of the pad electrode PDE may be vertically bent.

The pad electrode PDE may include the same material as the first, second, and third pixel electrodes PE1, PE2, and PE3 and may be formed through the same process as the first, second, and third pixel electrodes PE1, PE2, and PE3. According to some embodiments, the pad electrode PDE may include a first conductive layer CL1_P including ITO, a second conductive layer CL2_P including Ag, and a third conductive layer CL3_P including ITO that are sequentially stacked.

The pixel definition layer PDL may be located on a part of each of the first, second, and third pixel electrodes PE1, PE2, and PE3, the insulating layer IL, and the first partition wall PW1. For example, the pixel defining layer PDL may include a first pixel defining layer PDL1 and a second pixel defining layer PDL2.

The first pixel defining layer PDL1 may be located on a part of each of the first, second, and third pixel electrodes PE1, PE2, and PE3. Specifically, the first pixel defining layer PDL1 may not overlap the first partition wall PW1. In addition, the first pixel defining layer PDL1 may expose at least a part of the upper surface of each of the first, second, and third pixel electrodes PE1, PE2, and PE3. The first pixel defining layer PDL1 may have a substantially flat upper surface.

The first pixel defining layer PDL1 may include an inorganic material such as silicon oxide, silicon nitride, and the like. These may be used alone or in combination with each other. According to some embodiments, the first pixel defining layer PDL1 may include silicon oxide.

The first pixel defining layer PDL1 may extend to the pad area PDA and may be located on a part of the pad electrode PDE. The first pixel defining layer PDL1 may expose at least a part of an upper surface of the pad electrode PDE in the pad area PDA.

The second pixel defining layer PDL2 may be located on a part of the first pixel defining layer PDL1, one end of each of the first, second, and third pixel electrodes PE1, PE2, and PE and the first partition wall PW1. In addition, the second pixel defining layer PDL2 may expose at least a part of the upper surface of each of the first, second, and third pixel electrodes PE1, PE2, and PE3. The second pixel defining layer PDL2 may include an inorganic material such as silicon oxide, silicon nitride, and the like. These may be used alone or in combination with each other. The second pixel defining layer PDL2 may include an inorganic material different from an inorganic material of the first pixel defining layer PDL1. According to some embodiments, the second pixel defining layer PDL2 may include silicon nitride.

The second pixel defining layer PDL2 may be extend to the pad area PDA and may be located on the first insulating pattern IP1, one end of the pad electrode PDE, and the first pixel defining layer PDL1. The second pixel defining layer PDL2 may expose at least a part of an upper surface of the pad electrode PDE in the pad area PDA.

According to some embodiments, in the display area DA, a side surface of the first pixel defining layer PDL1 may protrude further in a direction away from a center of the second pixel defining layer PDL2 than a side surface of the second pixel defining layer PDL2. That is, a step may be formed between the first and second pixel defining layers PDL1 and PDL2.

According to some embodiments, the upper surface of the first partition wall PW1 may be positioned at the same level as the upper surface of the first pixel defining layer PDL1 with respect to the surface of the base substrate BS.

The second pad protection layer PL2_P may be located in the pad area PDA on the pad electrode PDE. The second pad protection layer PL2_P may protect the third conductive layer CL3_P including ITO of the pad electrode PDE. The second pad protection layer PL2_P may extend from the pad area PDA to at least a part of the upper surface of the second pixel defining layer PDL2. The second pad protection layer PL2_P may include a conductive material. According to some embodiments, the second pad protection layer PL2_P may include titanium nitride.

The first light emitting layer EML1 may be located in the first pixel area PX1 on the first pixel electrode PE1, the second light emitting layer EML2 may be located in the second pixel area PX2 on the second pixel electrode PE2, and the third light emitting layer EML3 may be located in the third pixel area PX3 on the third pixel electrode PE3. Each of the first, second, and third light emitting layers EML1, EML2, and EML3 may include an organic light emitting material that emits a light (e.g., a set or predetermined light or a set or predetermined color of light).

For example, the first light emitting layer EML1 may include a light emitting material that emits red light, the second light emitting layer EML2 may include a light emitting material that emits green light, and the third light emitting layer EML3 may include a light emitting material that emits blue light. That is, the light emitting layer may be independently located in each of the first, second, and third pixel areas PX1, PX2, and PX3. Alternatively, a plurality of light emitting layers including a light emitting material that emits the same light may be sequentially arranged in each of the first, second, and third pixel areas PX1, PX2, and PX3.

The second partition wall PW2 may be located in the display area DA on the second pixel defining layer PDL2. The second barrier rib PW2 may overlap the first partition wall PW1. For example, the second partition wall PW2 may include an inorganic material.

The second partition wall PW2 may have a multilayer structure. According to some embodiments, the second partition wall PW2 may include a first sub-layer SL1 and a second sub-layer SL2 located on the first sub-layer SL1 and including an inorganic material different from an inorganic material of the first sub-layer SL1. For example, the second sub-layer SL2 may include silicon nitride, and the second sub-layer SL2 may include silicon oxide. However, embodiments of the present disclosure are not limited thereto.

A width of the first sub-layer SL1 may be smaller than a width of the second sub-layer SL2. According to some embodiments, a side surface of the second sub-layer SL2 may protrude further in a direction away from a center of the first sub-layer SL1 than a side surface of the first sub-layer SL1. That is, the second sub-layer SL2 and the first sub-layer SL1 may define an undercut shape.

Due to the undercut shape, leakage current between adjacent pixel areas may be reduced. In addition, the second partition wall PW2 may be serve as a spacer supporting a fine metal mask (FMM) used in a process of forming the first, second, and third light emitting layers EM1L, EML2, and EML3.

The second insulating pattern IP2 may be located in the pad area PDA on the second pixel defining layer PDL2 and the second pad protection layer PL2_P. The second insulating pattern IP2 may cover a side part of the second pad protection layer PL2_P. In addition, the second insulating pattern IP2 may expose at least a part of the upper surface of the second pad protection layer PL2_P. The second insulating pattern IP2 may include the same material as the second partition wall PW2 and may be formed through the same process material as the second partition wall PW2.

The common electrode CTE may be located on the second pixel defining layer PDL2, the first, second, and third light emitting layers EML1, EML2, and EML3, and the second partition wall PW2. The common electrode CTE may be located on an entire surface of the display area DA. For example, the common electrode CTE may include a metal, an alloy, a metal nitride, a conductive metal oxide, a transparent conductive material, and the like. These may be used alone or in combination with each other.

Accordingly, the first light emitting element LED1 including the first pixel electrode PE1, the first light emitting layer EML1, and the common electrode CTE may be located in the first pixel area PX1, the second light emitting element LED2 including the second pixel electrode PE2, the second light emitting layer EML2, and the common electrode CTE may be located in the second pixel area PX2, and the third light emitting element LED3 including the third pixel electrode PE3, the third light emitting layer EML3, and the common electrode CTE may be located in the third pixel area PX3.

The encapsulation layer ENC may be located in the display area DA on the common electrode CTE. The encapsulation layer ENC may be located on an entire surface of the display area DA. The encapsulation layer ENC may prevent or reduce instances of contaminants, impurities, moisture, or the like from permeating the first, second, and third light emitting elements LE1, LED2, and LED3 from the outside. The encapsulation layer ENC may include at least one inorganic layer and at least one organic layer. For example, the inorganic layer may include silicon oxide, silicon nitride, silicon oxynitride, and the like. These may be used alone or in combination with each other. The organic layer may include a polymer cured material such as polyacrylate.

The display device DD according to some embodiments of the present disclosure may be a display device that displays an image. For example, the display device DD may be a display device such as an organic light emitting display device, a liquid crystal display device, an organic light emitting diode on silicon substrate (“OLEDos”), a liquid crystal on silicon substrate (“LCos”), or a light emitting diode on silicon substrate (“LEDos”). According to some embodiments, the display device DD may be a display device such as OLEDos.

For example, if the display device DD is a display device such as OLEDos, the display device DD may constitute a head-mounted display, which is a virtual reality or augmented reality glasses-type monitor device that is worn in the form of glasses or a helmet and focuses on a distance close to the user's eyes. However, embodiments of the present disclosure are not limited thereto, and the display device DD may configure various displays.

The display device DD according to some embodiments of the present disclosure may include the first, second, and third pixel electrodes PE1, PE2, and PE3 respectively located on the first, second, and third pixel areas PX1, PX2, and PX2 on the base substrate BS, the first partition wall PW1 located between two pixel electrodes among the first, second, and third pixel electrodes PE1, PE2, and PE3, the first pixel defining layer PDL1 located on a part of each of the first, second, and third pixel electrodes PE1, PE2, and PE3 and exposing at least a part of an upper surface of each of the first, second, and third pixel electrodes PE1, PE2, and PE3, and the second pixel defining layer PDL2 located on the first partition wall PW1. Here, with respect to the surface of the base substrate BS, an upper surface of the first partition wall PW1 may be positioned at the same level as an upper surface of the first pixel defining layer PDL1. Accordingly, a light emitting layer including a light emitting material that emits one color can be independently located in each of the first, second, and third pixel areas PX1, PX2, and PX3. In addition, power consumption of the display device DD can be reduced.

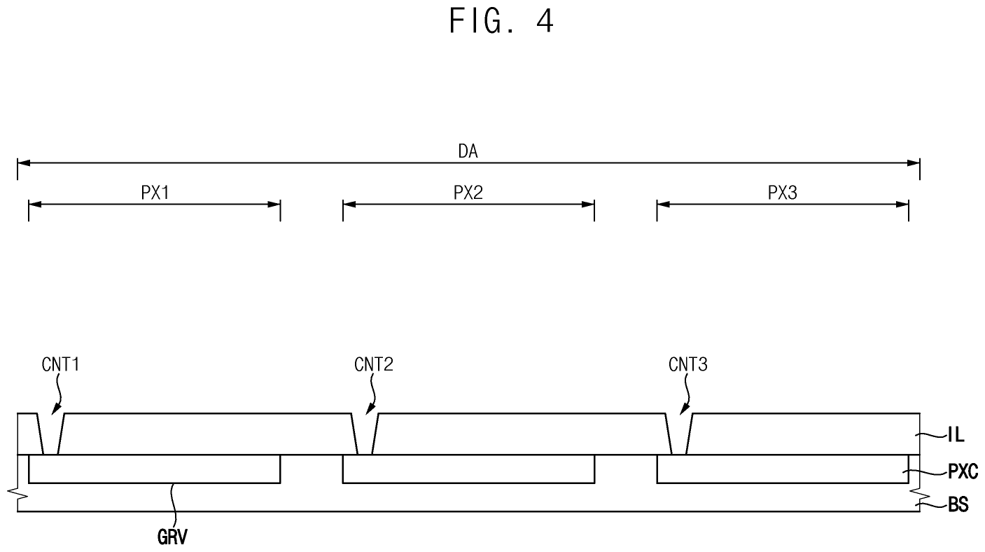

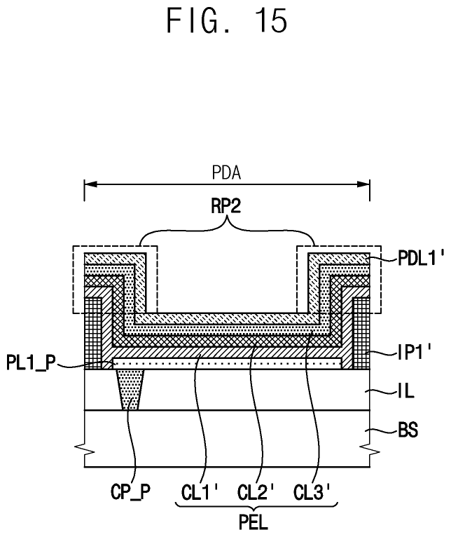

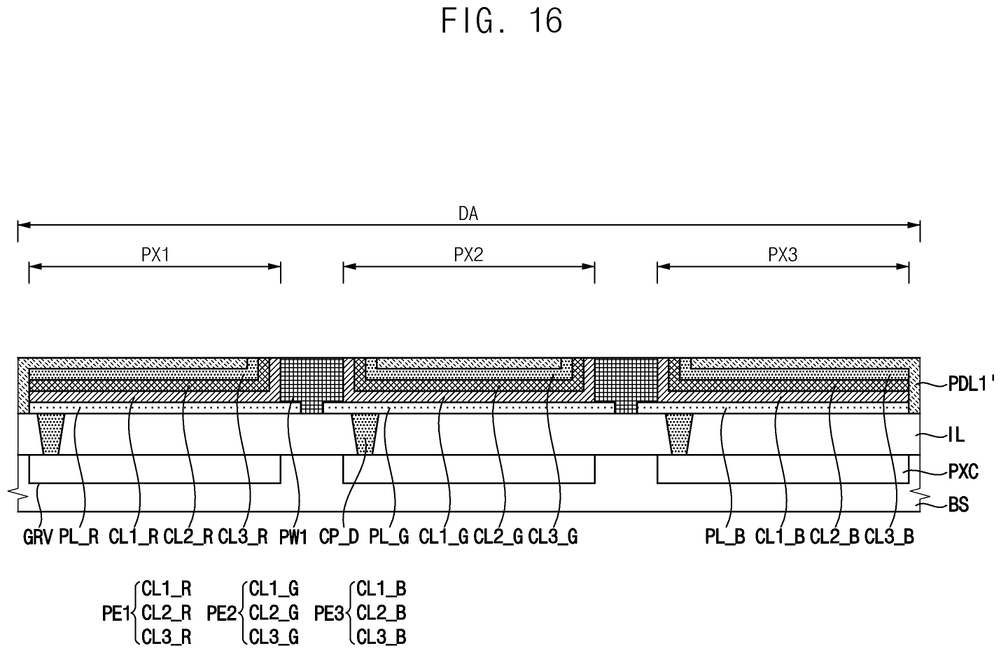

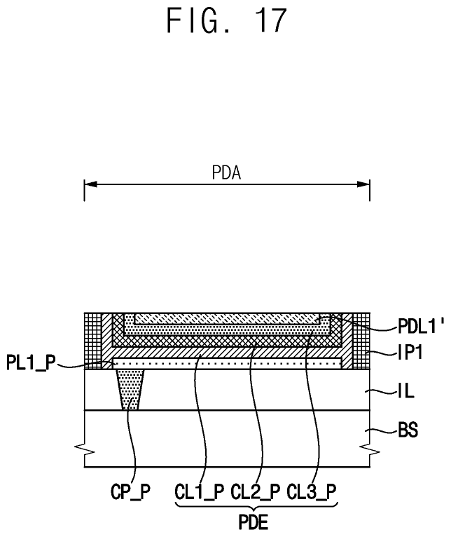

FIGS. 4 to 25 are cross-sectional views for explaining a method for manufacturing the display device of FIGS. 2 and 3. For example, FIGS. 4, 6, 8, 10, 12, 14, 16, 18, and 22 to 25 are cross-sectional views for explaining a method for manufacturing the display device DD of FIG. 2 and FIGS. 3, 5, 7, 9, 11, 13, 15, 17, and 19 to 21 are cross-sectional views for explaining a method for manufacturing the display device DD of FIG. 3.

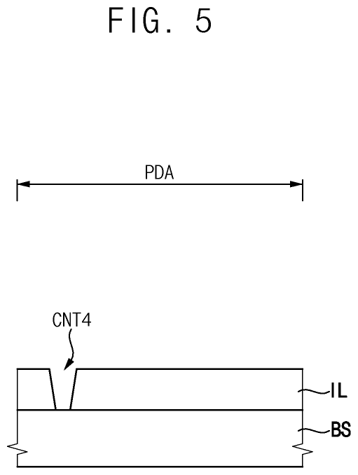

Referring to FIGS. 4 and 5, the plurality of grooves GRV may be formed in the base substrate BS in the display area DA. Each of the grooves GRV may overlap each of the first pixel area PX1, the second pixel area PX2, and the third pixel area PX3. The base substrate BS may be formed of a silicon wafer. In addition, the pixel circuit portion PXC may be formed in each of the grooves GRV.

The insulating layer IL may be formed on the base substrate BS. For example, the insulating layer IL may be formed using an inorganic material such as silicon oxide, silicon nitride, and the like.

In the first pixel area PX1, a first contact hole CNT1 may be formed by removing a part of the insulating layer IL to expose a part of the pixel circuit portion PXC. In the second pixel area PX2, a second contact hole CNT2 may be formed by removing a part of the insulating layer IL to expose a part of the pixel circuit portion PXC. In the third pixel area PX3, a third contact hole CNT3 may be formed by removing a part of the insulating layer IL to expose a part of the pixel circuit portion PXC. In addition, in the pad area PDA, a fourth contact hole CNT4 exposing a part of the base substrate BS by removing a part of the insulating layer IL may be formed. The first, second, third, and fourth contact holes CNT1, CNT2, CNT3, and CNT4 may be formed simultaneously.

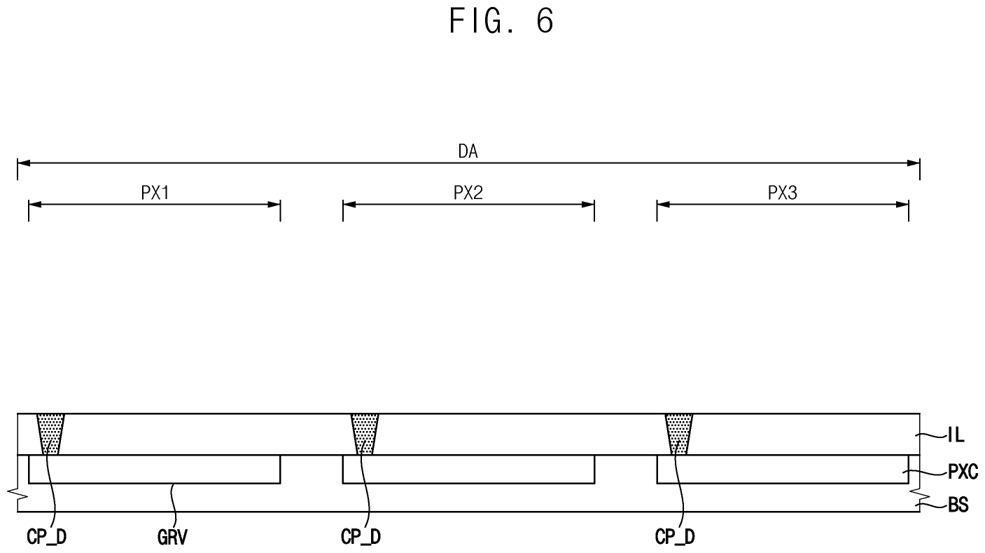

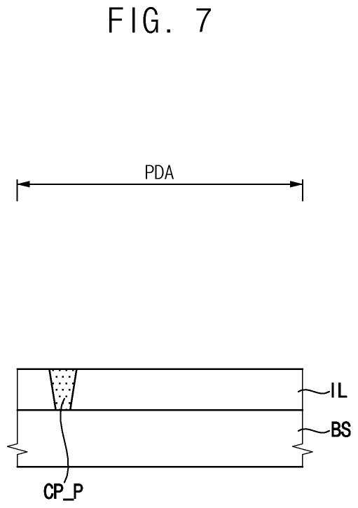

Further referring to FIGS. 6 and 7, each of the first, second, and third contact holes CNT1, CNT2, and CNT3 may be filled with the pixel connection pattern CP_D. In addition, the fourth contact hole CNT4 may be filled with the pad connection pattern CP_P. For example, each of the pixel connection pattern CP_D and the pad connection pattern CP_P may be formed using tungsten.

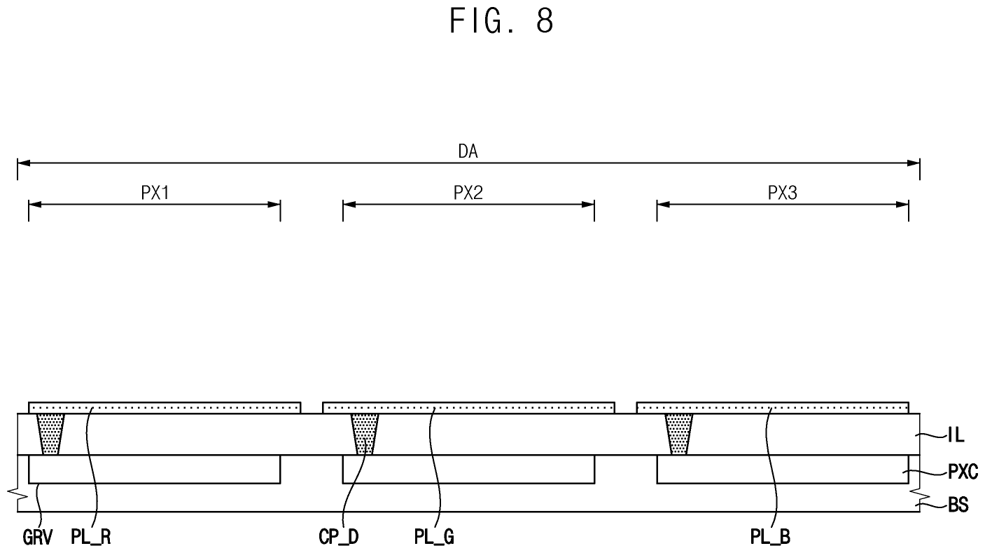

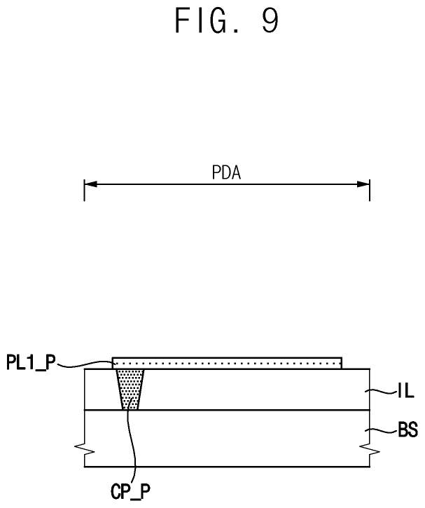

Further referring to FIGS. 8 and 9, the first, second, and third pixel protection layers PL_R, PL_G, and PL_B may be formed in the display area DA on the insulating layer IL. For example, the first pixel protection layer PL_R may overlap the first pixel area PX1, the second pixel protection layer PL_G may overlap the second pixel area PX2, and the third pixel protection layer PL_B may overlap the third pixel area PX3. Each of the first, second, and third pixel passivation layers PL_R, PL_G, and PL_B may be electrically connected to the pixel connection pattern CP_D.

The first pad protection layer PL1_P may be formed in the pad area PDA on the insulating layer IL. The first pad protection layer PL1_P may be electrically connected to the pad connection pattern CP_P.

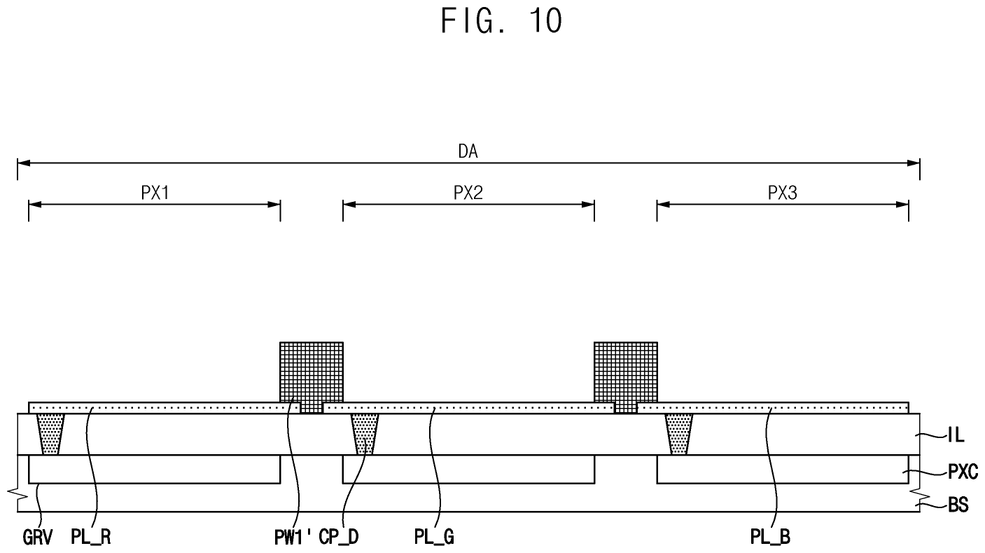

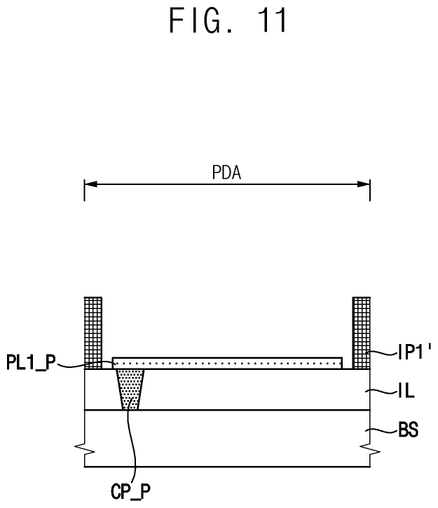

Further referring to FIGS. 10 and 11, a preliminary first partition wall PW1′ may be formed in the display area DA on the insulating layer IL. The preliminary first partition wall PW1′ may be formed between two pixel protection layers among the first, second, and third pixel protection layers PL_R, PL_G, and PL_B. Specifically, the preliminary first partition wall PW1′ may be formed along a boundary between two pixel protection layers among the first, second, and third pixel protection layers PL_R, PL_G, and PL_B.

A preliminary first insulating pattern IP1′ may be formed in the pad area PDA on the insulating layer IL. The preliminary first insulating pattern IP1′ may be simultaneously formed through the same process as the preliminary first partition wall PW1′.

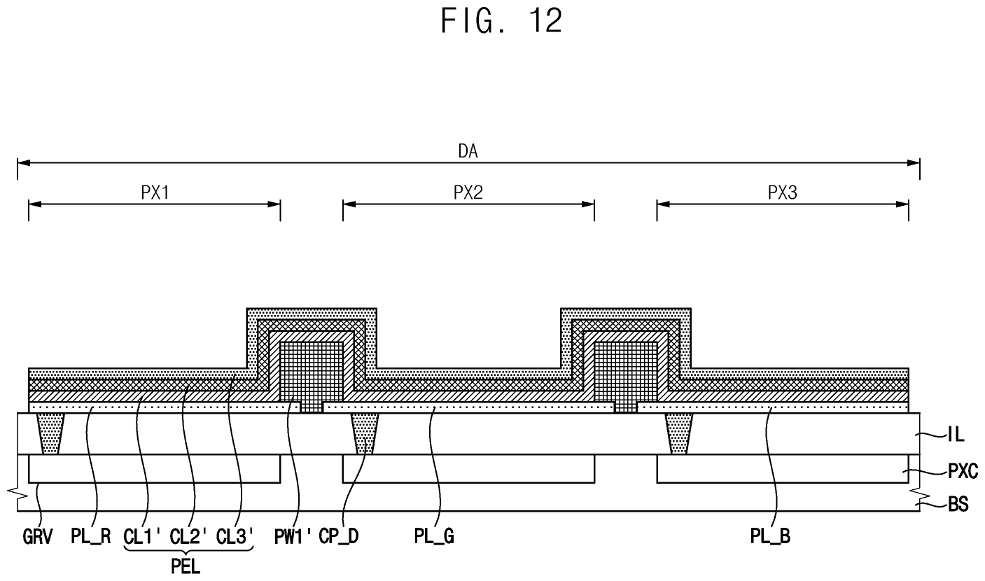

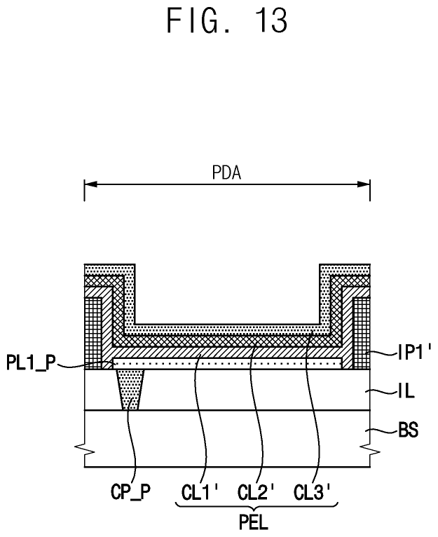

Further referring to FIGS. 12 and 13, a preliminary electrode layer PEL may be formed on the first, second, and third pixel protection layers PL_R, PL_G, and PL_B and the preliminary first partition wall PW1′ to cover the preliminary first partition wall PW1′ and the preliminary first insulating pattern IP1′. That is, the preliminary electrode layer PEL may be formed in the display area DA and may extend to the pad area PDA. For example, the preliminary electrode layer PEL may be formed to have a uniform thickness along a profile each of the preliminary first partition wall PW1′ and the preliminary first insulating pattern IP1′.

For example, the preliminary electrode layer PEL may include first, second, and third conductive layers CL1′, CL2′, and CL3′ that are sequentially stacked. The first conductive layer CL1′ may be formed using ITO, the second conductive layer CL2′ may be formed using Ag, and the third conductive layer CL3′ may be formed using ITO.

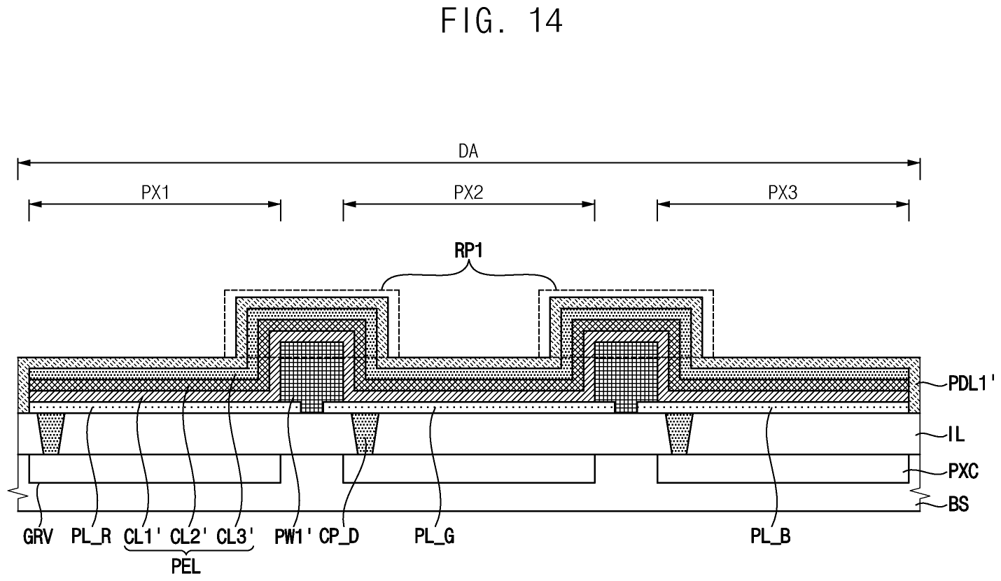

Further referring to FIGS. 14, 15, 16, and 17, a preliminary first pixel defining layer PDL1′ may be formed on the preliminary electrode layer PEL. The preliminary first pixel defining layer PDL1′ may be formed in the display area DA and may extend to the pad area PDA. For example, the preliminary first pixel defining layer PDL1′ may be formed to have a uniform thickness along a profile of the preliminary electrode layer PEL. For example, the preliminary first pixel defining layer PDL1′ may be formed using an inorganic material such as silicon oxide, silicon nitride, and the like.

According to some embodiments, after the preliminary electrode layer PEL and the preliminary first pixel defining layer PDL1′ are formed, a planarization process may be performed on an entire surface of the base substrate BS. For example, the planarization process may be a chemical mechanical planarization (“CMP”) process.

Through the planarization process, a part (i.e., a first removal part RP1) of each of the preliminary first partition wall PW1′, the preliminary electrode layer PEL, and the preliminary first pixel defining layer PDL1′ in the display area DA may be removed. In addition, through the planarization process, a part (i.e., a second removal part RP2) of each of the preliminary first insulating pattern IP1′, the preliminary electrode layer PEL, and the preliminary first pixel defining layer PDL1′ in the pad area PDA may be removed. Here, the first removal part RP1 may refer to a protruding part of the preliminary first partition wall PW1′, the preliminary electrode layer PEL, and the preliminary first pixel defining layer PDL1′, and the second removal part RP2 may refer to a protruding part of the preliminary first insulating pattern IP1′, the preliminary electrode layer PEL, and the preliminary first pixel defining layer PDL1′.

By performing the planarization process, the first pixel electrode PE1 may be formed on the first pixel protection layer PL_R, the second pixel electrode PE2 may be formed on the second pixel protection layer PL_G, and the third pixel electrode PE3 may be formed on the third pixel protection layer PL_B in the display area DA. In addition, by performing the planarization process, the first partition wall PW1 may be formed between the first and second pixel electrodes PE1 and PE2 and between the second and third pixel electrodes PE2 and PE3, and the first insulating pattern IP1 may be formed outside the pad electrode PDE. Meanwhile, after performing the planarization process, the preliminary first pixel defining layer PDL1′ may remains on each of the first, second, and third pixel electrodes PE1, PE2, and PE3, and the pad electrode PDE, and may not overlap the first partition wall PW1 and the first insulating pattern IP1.

According to some embodiments, after the first, second, and third pixel electrodes PE1, PE2, and PE3 and the first partition wall PW1 are formed, at least one end of each of the first, second, and third pixel electrodes PE1, PE2, and PE3 may be vertically bent, and the upper surface of the first partition wall PW1 may be positioned at the same level as an upper surface of the preliminary first pixel defining layer PDL1′ with respect to the surface of the base substrate BS. In addition, after the first, second, and third pixel electrodes PE1, PE2, and PE3 and the first partition wall PW1 are formed, the upper surface of vertically bent one end of each of the first, second, and third pixel electrodes PE1, PE2, and PE3 may be positioned at the same level as an upper surface of each of the first partition wall PW1 and the preliminary first pixel defining layer PDL1′ with respect to the surface of the base substrate BS.

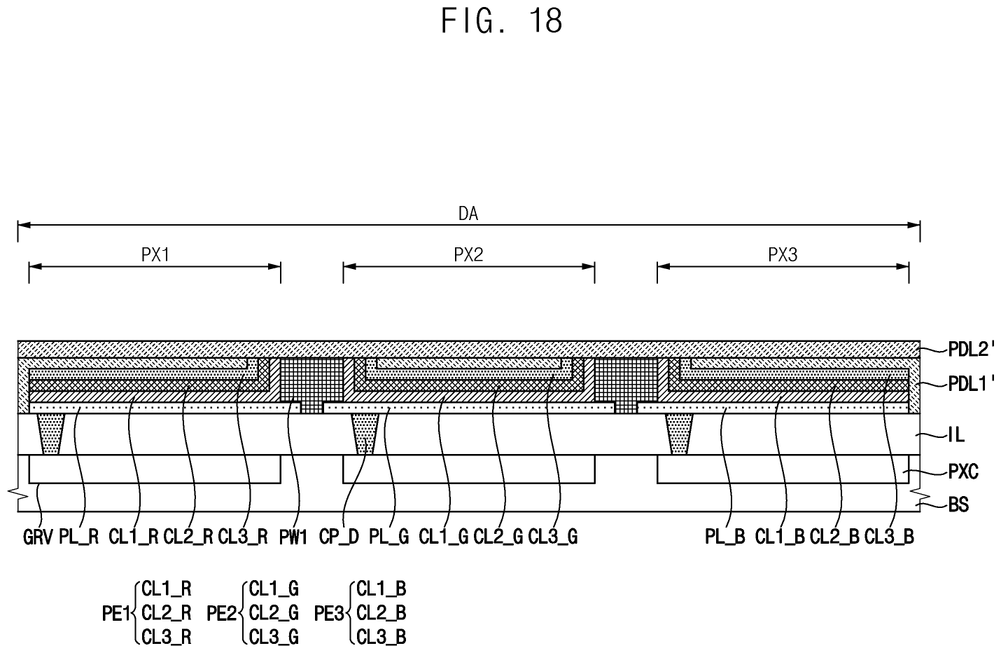

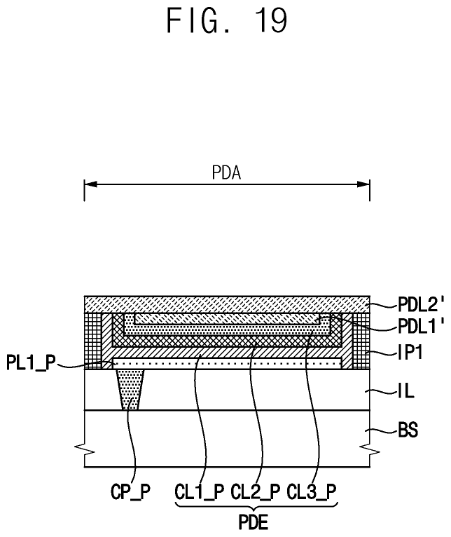

Further referring to FIGS. 18 and 19, a preliminary second pixel definition layer PDL2′ may be formed on the first partition wall PW1, the first, second, and third pixel electrodes PE1, PE2, and PE3, and the preliminary first pixel defining layer PDL1′. The preliminary second pixel defining layer PDL2′ may be formed in the display area DA and may extend to the pad area PDA. For example, the preliminary second pixel defining layer PDL2′ may be formed using an inorganic material such as silicon oxide, silicon nitride, and the like.

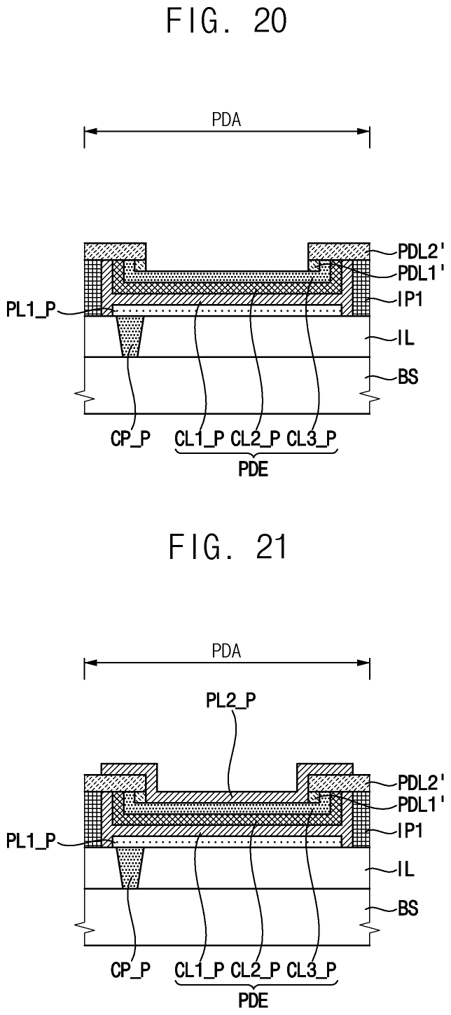

Further referring to FIG. 20, in the pad area PDA, a part of each of the preliminary first pixel defining layer PDL1′ and the preliminary second pixel defining layer PDL2′ may be removed. In the pad area PDA, as the part of each of the preliminary first pixel defining layer PDL1′ and the preliminary second pixel defining layer PDL2′ are removed, at least a part of an upper surface of the pad electrode PDE may be exposed.

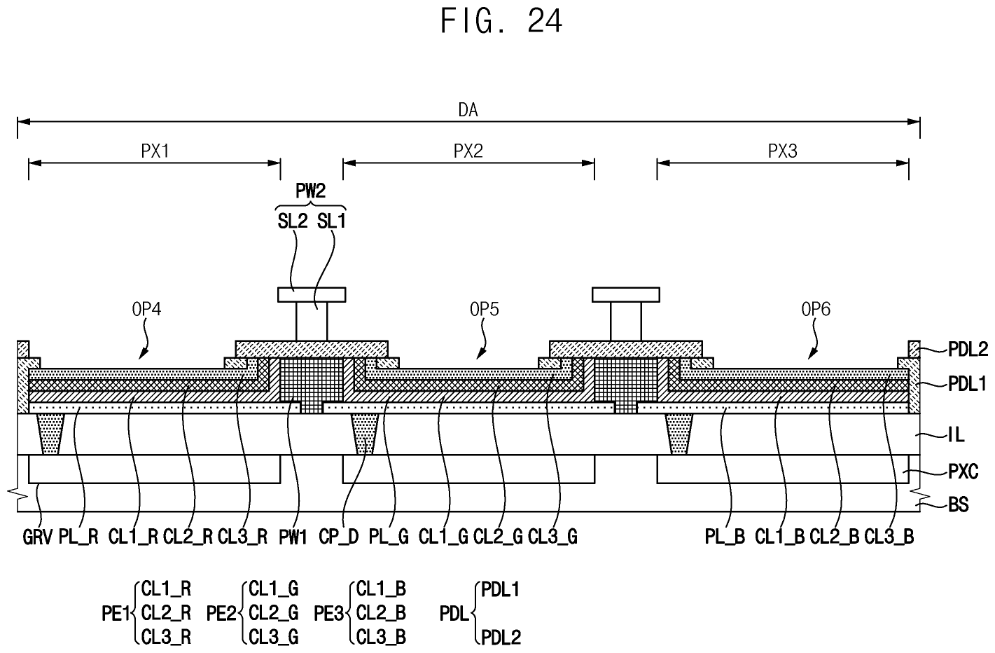

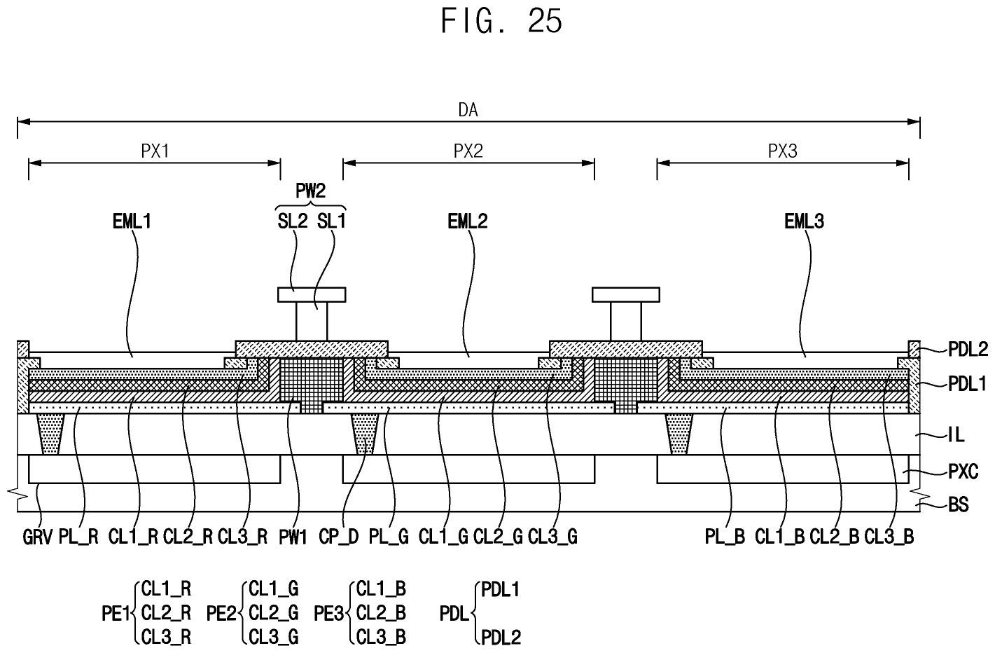

Further referring to FIG. 21, the second pad protection layer PL2_P may be formed on the pad electrode PDE. The second pad protection layer PL2_P may extend to at least a part of an upper surface of the preliminary second pixel defining layer PDL2′. For example, the second pad protection layer PL2_P may be formed of titanium nitride. The preliminary first pixel defining layer PDL1′ and the preliminary second pixel defining layer PDL2′ illustrated in FIG. 21 may be defined as the first pixel defining layer PDL1 and the second pixel defining layer PDL2 after the first pixel defining layer PDL1 and the second pixel defining layer PDL2 illustrated in FIG. 24, respectively.

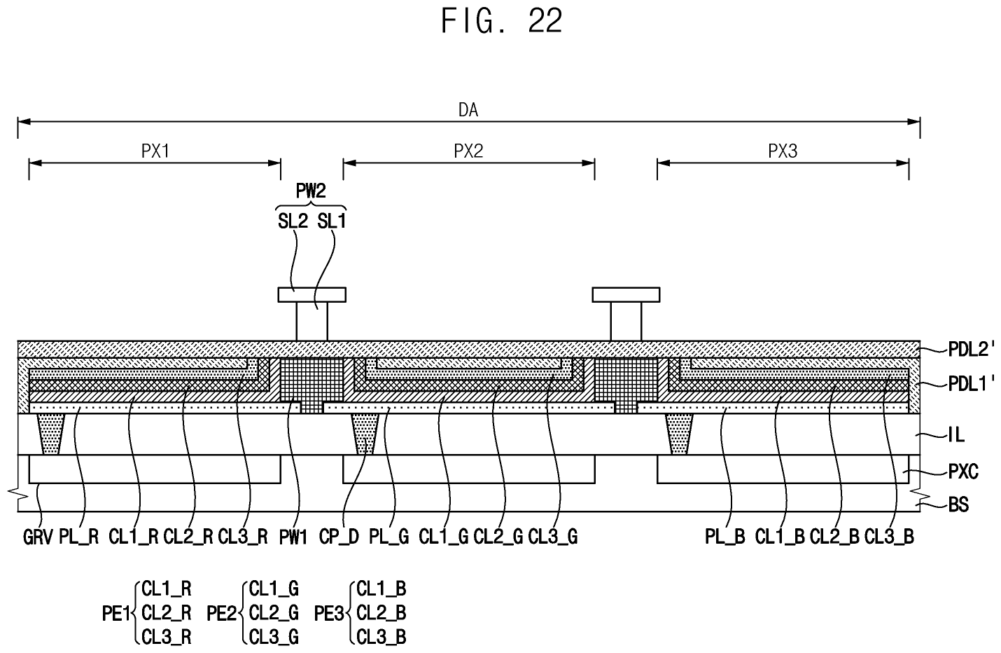

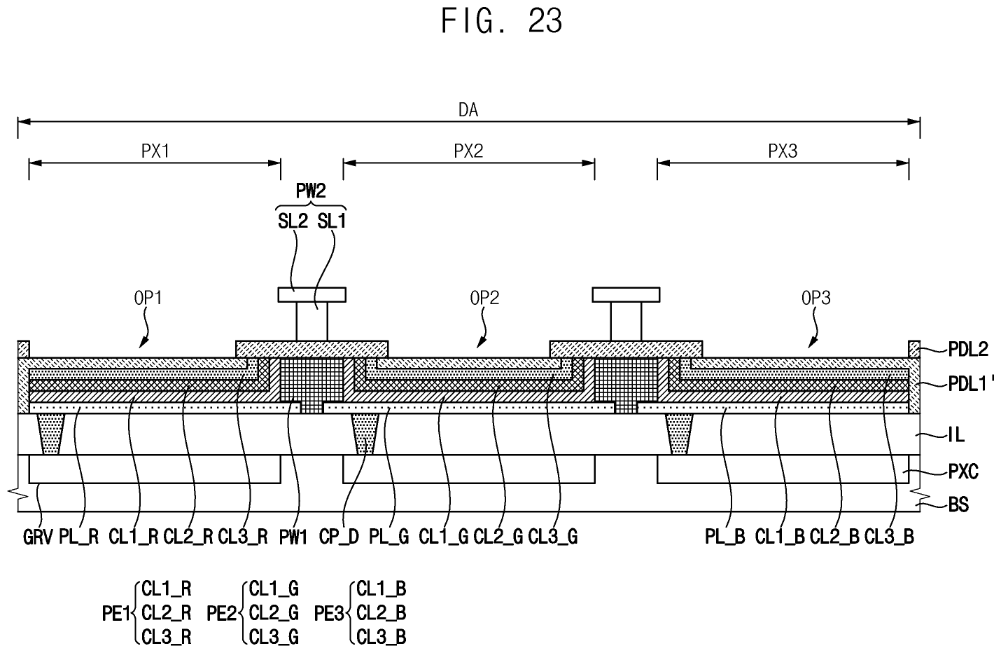

Referring further to FIG. 22, in the display area DA, a second partition wall PW2 may be formed on the preliminary second pixel defining layer PDL2′. Specifically, the second partition wall PW2 may be formed to overlap the first partition wall PW1. The second partition wall PW2 may have a multi-layer structure including the first sub-layer SL1 and the second sub-layer SL2 formed on the first sub-layer SL1. The first sub-layer SL1 and the second sub-layer SL2 may be formed of different inorganic materials. As the first sub-layer SL1 and the second sub-layer SL2 are formed of different inorganic materials, the second sub-layer SL2 and the first sub-layer SL1 may define an undercut shape.

Referring to FIG. 23, a first opening OP1 may be formed by removing a part of the second preliminary pixel defining layer PDL2′ in the first pixel area PX1, a second opening OP2 may be formed by removing a part of the second preliminary pixel defining layer PDL2′ in the second pixel area PX2, and a third opening OP3 may be formed by removing a part of the second preliminary pixel defining layer PDL2′ in the third pixel area PX3. Accordingly, the second defining layer PDL2 formed the first opening OP1 exposing at least a part of an upper surface of the preliminary first pixel defining layer PDL1′ in the first pixel area PX1, the second opening OP2 exposing at least a part of an upper surface of the preliminary first pixel defining layer PDL1′ in the second pixel area PX2, and the third opening OP3 exposing at least a part of an upper surface of the preliminary first pixel defining layer PDL1′ in the third pixel area PX3 may be formed.

Referring to FIG. 24, a fourth opening OP4 may be formed by removing a part of the preliminary first pixel defining layer PDL1′ in the first pixel area PX1, a fifth opening OP5 may be formed by removing a part of the preliminary first pixel defining layer PDL1′ in the second pixel area PX2, and a sixth opening OP6 may be formed by removing a part of the preliminary first pixel defining layer PDL1′ in the third pixel area PX3. Accordingly, the first defining layer PDL1 formed the fourth opening OP4 exposing at least a part of an upper surface of the first pixel electrode PE1 in the first pixel area PX1, the fifth opening OP5 exposing at least a part of an upper surface of the second pixel electrode PE2 in the second pixel area PX1, and the sixth opening OP6 exposing at least a part of an upper surface of the third pixel electrode PE3 in the third pixel area PX3 may be formed. The first opening OP1 may be connected to the fourth opening OP4, the second opening OP2 may be connected to the fifth opening OP5, and the third opening OP3 may be connected to the sixth opening OP6.

Referring to FIG. 25, the first light emitting layer EML1 may be formed on the first pixel electrode PE1, the second light emitting layer EML2 may be formed on the second pixel electrode PE2, and the third light emitting layer EML3 may be formed on third pixel electrode PE3. Specifically, the first light emitting layer EML1 may be formed in the first and fourth openings OP1 and OP4, the second light emitting layer EML2 may be formed in the second and fifth openings OP2 and OP5, and the third light emitting layer EML3 may be formed in the third and sixth openings OP3 and OP6.

Referring back to FIG. 2, the common electrode CTE may be formed on the second pixel defining layer PDl2, the first, second, and third light emitting layers EML1, EML2, and EML3, and the second partition wall PW2. The common electrode CTE may be formed on the entire surface of the display area DA.

The encapsulation layer ENC may be formed on the common electrode CTE. The encapsulation layer ENC may be formed on the entire surface of the display area DA. The encapsulation layer ENC may include at least one inorganic layer and at least one organic layer.

Accordingly, the display device DD illustrated in FIGS. 2 and 3 may be manufactured.

In the method for manufacturing the display device DD according to some embodiments of the present disclosure, the preliminary electrode layer PEL may be formed on the base substrate BS, and a part of the preliminary electrode layer PEL may be removed through a planarization process to form a pixel electrode (e.g., the first, second, and third pixel electrodes PE1, PE2, and PE3). Accordingly, the pixel electrode can be easily formed.

Aspects of embodiments according to the present disclosure can be applied to various display devices. For example, embodiments according to the present disclosure may be applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although aspects of some embodiments have been described, those skilled in the art will readily appreciate that many modifications are possible in the embodiments without materially departing from the novel teachings and characteristics of embodiments according to some embodiments of the present disclosure. Accordingly, all such modifications are intended to be included within the scope of embodiments of the present disclosure as defined in the claims, and their equivalents. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, and their equivalents.

What is claimed is:

1. A display device comprising:
a base substrate including a first pixel area and a second pixel area;
a first pixel electrode in the first pixel area on the base substrate;
a second pixel electrode in the second pixel area on the base substrate;
a first partition wall between the first pixel electrode and the second pixel electrode; and
a first pixel defining layer on a part of each of the first and second pixel electrodes, exposing at least a part of an upper surface of each of the first and second pixel electrodes, and having an upper surface at a same level as an upper surface of the first partition wall with respect to a surface of the base substrate.

2. The display device of claim 1, wherein at least one end of each of the first and second pixel electrodes is vertically bent, and
an upper surface of the one end of each of the first and second pixel electrodes is at a same layer as the upper surface of each of the first partition wall and the first pixel defining layer with respect to the surface of the base substrate.

3. The display device of claim 1, further comprising:
a first pixel protection layer between the base substrate and the first pixel electrode and including a conductive material; and
a second pixel protection layer between the base substrate and the second pixel electrode and including a same conductive material as the first pixel protection layer.

4. The display device of claim 3, wherein each of the first and second pixel protection layers includes titanium nitride (TiN).

5. The display device of claim 1, further comprising:
a second pixel defining layer on a part of the first pixel defining layer and the first partition wall and exposing at least a part of the upper surface of each of the first and second pixel electrodes.

6. The display device of claim 5, wherein the first pixel defining layer and the second pixel defining layer include different inorganic materials.

7. The display device of claim 5, wherein the first pixel defining layer includes silicon oxide (SiOₓ) and the second pixel defining layer includes silicon nitride (SiNₓ).

8. The display device of claim 5, wherein a side surface of the first pixel defining layer protrudes further in a direction away from a center of the second pixel defining layer than a side surface of the second pixel defining layer.

9. The display device of claim 5, further comprising:
a second partition wall on the second pixel defining layer, overlapping the first partition wall, and including an inorganic material.

10. The display device of claim 9, wherein the second partition wall includes:
a first sub-layer; and
a second sub-layer on the first sub-layer and including an inorganic material different from an inorganic material of the first sub-layer.

11. The display device of claim 10, wherein a side surface of the second sub-layer protrudes further in a direction away from a center of the first sub-layer than a side surface of the first sub-layer.

12. The display device of claim 1, wherein the base substrate further includes a third pixel area,
further comprising:
a third pixel electrode in the third pixel area on the base substrate;
a first light emitting layer on the first pixel electrode and including a light emitting material configured to emit red light;
a second light emitting layer on the second pixel electrode and including a light emitting material configured to emit green light; and
a third light emitting layer on the third pixel electrode and including a light emitting material configured to emit blue light.

13. The display device of claim 1, wherein the first partition wall includes silicon nitride.

14. The display device of claim 1, wherein the base substrate includes a silicon wafer.

15. A method for manufacturing a display device, the method comprising:
forming a preliminary first partition wall on a base substrate including a first pixel area and a second pixel area;
forming a preliminary electrode layer covering the preliminary first partition wall on the base substrate and the preliminary first partition wall;
forming a preliminary first pixel defining layer on the preliminary electrode layer;
forming a first pixel electrode in the first pixel area, a second pixel electrode in the second pixel area, and a first partition wall between the first and second pixel electrodes by performing a planarization process on an entire surface of the base substrate; and
forming a first pixel defining layer exposing at least a part of an upper surface of each of the first and second pixel electrodes by removing a part of the preliminary first pixel defining layer.

16. The method of claim 15, wherein in the forming the first pixel electrode, the second pixel electrode, and the first partition wall, a part of each of the preliminary first partition wall, the preliminary electrode layer, and the preliminary first pixel defining layer is removed, and
at least one end of each of the first and second pixel electrodes is vertically bent and an upper surface of the first partition wall is positioned at a same level as an upper surface of the preliminary first pixel defining layer with respect to a surface of the base substrate after the forming the first pixel electrode, the second pixel electrode, and the first partition wall.

17. The method of claim 15, wherein in the forming the preliminary electrode layer, the preliminary electrode layer is formed to have a uniform thickness along a profile of the preliminary first partition wall, and
in the forming the preliminary first pixel defining layer, the preliminary first pixel defining layer is formed to have a uniform thickness along a profile of the preliminary electrode layer.

18. The method of claim 15, wherein the forming the first pixel electrode, the second pixel electrode, and the first partition wall is performed through a chemical mechanical planarization (“CMP”) process.

19. The method of claim 15, before the forming the first partition wall, further comprising:
forming a first pixel protection layer including a conductive material in the first pixel area on the base substrate; and
forming a second pixel protection layer including a same conductive material as the first pixel protection layer in the second pixel area on the base substrate,
wherein the first pixel protection layer is formed between the base substrate and the first pixel electrode and the second pixel protection layer is formed between the base substrate and the second pixel electrode.

20. The method of claim 15, after the first pixel electrode, the second pixel electrode, and the first partition wall and before the first pixel defining layer, further comprising:
forming a preliminary second pixel defining layer on the first partition wall, the first pixel electrode, the second pixel electrode, and the preliminary first pixel defining layer; and
forming a second pixel defining layer exposing at least a part of an upper surface of the preliminary first pixel defining layer in each of the first and second pixel areas,
wherein after the forming the first pixel defining layer, the second pixel defining layer exposes at least a part of an upper surface of each of the first and second pixel electrodes.
